(19) United States
(12) Patent Application Publication
(10) Pub. No.: US 2026/0153537 A1
(43) Pub. Date: Jun. 4, 2026

(54) Method and Device for Measuring a Voltage

(71) Applicant: Northrop Grumman Litef GmbH, Freiburg (DE)

(72) Inventor: Stefan König, Staufen (DE)

(21) Appl. No.: 19/113,089

(22) PCT Filed: Oct. 10, 2023
(86) PCT No.: PCT/EP2023/077992

§ 371 Date: Feb. 10, 2026

(30) Foreign Application Priority Data
Oct. 14, 2022 (DE) 10 2022 126 948.5

(51) Int. Cl. G01R 15/14; B81B 3/00; G01R 9/00; G01R 19/25; G01R 35/00

(52) U.S. Cl. CPC G01R 15/144; B81B 3/0021; G01R 9/00; G01R 19/2503; G01R 35/007; B81B 2201/0235; B81B 2201/0285; B81B 2201/0292; B81B 2203/0109; B81B 2203/04; B81B 2203/051

(57) ABSTRACT

A method for measuring a voltage using a microelectromechanical system, MEMS, (100) comprising a sample mass (110) which is supported above a substrate by means of mechanical spring elements (120) in such a way that it can be moved relative to the substrate along a vibration direction (x), trimming electrodes (130) which are suitable for generating an electrostatic force on the sample mass (110) when a voltage is applied to them, the electrostatic force counteracting a mechanical spring force generated by the spring elements (120) when the sample mass (110) is deflected along the vibration direction (x), drive electrodes (140) which are suitable for setting the sample mass (110) in motion along the vibration direction (x), and readout electrodes (150) which are suitable for measuring a vibration frequency of the vibration of the sample mass (110) generated in such a way comprises: applying a voltage to be measured to the trimming electrodes (130); measuring the magnitude of the voltage to be measured from the measured vibration frequency of the sample mass (110); and detecting changes in the voltage to be measured on the basis of the change in the measured vibration frequency.

### TECHNICAL FIELD

The present invention relates to a method for measuring a voltage by means of a micro-electro-mechanical system and to such a micro-electro-mechanical system.

### BACKGROUND

Reference voltage sources are used in a variety of electronic applications to predetermine a voltage on the basis of which further operations are carried out. For example, reference voltages are used in analog-to-digital converters to sample the analog signal. Other parameters used in the corresponding electronic component, such as voltage values or electricity variables, are also established or calculated based on reference voltages.

Particularly in case of acceleration or angular rate sensors that are designed as micro-electro-mechanical systems, MEMS, reference voltages are needed to set the drive and/or readout voltages used to predetermined or predeterminable values. For example, the measuring accuracy of acceleration sensors typically scales quadratically with the voltage applied between a vibration mass of the sensor and its drive/readout electrodes. The so-called scale factor, which converts the measurable change in capacitance or charge caused by the deflection of the sample mass into the acceleration of actual interest, is therefore quadratically dependent on this drive readout voltage. As this, in turn, is generated or set based on a reference voltage, the scale factor depends quadratically on the magnitude of the reference voltage.

High-performance components, such as high-precision acceleration or angular rate sensors, are subject to the requirement that they are stable over the long term, i.e., that their calculation or measurement results are of the same quality over a very long time, e.g., over 10 years or more, and, in particular, that there is no temporal drift, i.e., no continuous increase or decrease.

Here, a deviation of less than 100 ppm per year is acceptable for the scale factor of acceleration sensors when, for example, the operating and environmental conditions remain constant during the product life cycle of the acceleration sensor, i.e., a deviation that is only 100 millionths of the scale factor at the beginning of the product life cycle.

However, typical reference voltage sources only achieve an accuracy in the order of magnitude of 50 ppm per year, for example. Due to the quadratic dependence of the scale factor on the reference voltage, this already results in a change in the scale factor of 100 ppm per year. If the aging effects of other components are also taken into account, this results in a drift of the scale factor, and thus of the measured values, of at least 300 ppm per year for a typically implementable acceleration sensor. This also influences the accuracy of the measurement via the offset/bias of the sensor up to values of 50 to 100 μg, which is too much for a high-precision acceleration sensor without correction.

The inaccuracies of other electronic components that occur over time can also be estimated in a similar way. Here, too, the temporal drift of reference voltages is often mainly responsible for the drift of the overall component.

In this process, improvement of the accuracy of reference voltage sources is not possible or only possible in a complicated way. In addition, there is the problem that the direct measurement of the reference voltages is afflicted with a similar temporal drift or intrinsic measurement inaccuracy, which is similar in magnitude to the drift of the reference voltage.

### SUMMARY

The object of the present invention is therefore to specify a method for measuring a voltage, in particular a reference voltage, which is sufficiently accurate to detect the long-term drift of the voltage. The object of the present invention is also to specify a device which can implement such a method.

A method for measuring a voltage uses a micro-electro-mechanical system, MEMS, is described. The MEMS has a sample mass which is mounted above a substrate by means of mechanical spring elements in such a way that it can be moved relative to the substrate along a direction of vibration, trim electrodes which are suitable for generating an electrostatic force on the sample mass when a voltage is applied to them, the electrostatic force counteracting a mechanical spring force generated by the spring elements when the sample mass is deflected along the direction of vibration, drive electrodes which are suitable for setting the sample mass in motion along the direction of vibration, and readout electrodes which are suitable for measuring a vibration frequency of the vibration of the sample mass generated in such a way. The method comprises: applying a voltage to be measured to the trim electrodes; measuring the magnitude of the voltage to be measured from the measured vibration frequency of the sample mass; and detecting changes in the voltage to be measured on the basis of the change in the measured vibration frequency.

The detection of the voltage to be measured is therefore achieved by determining the vibration frequency of a vibration system. Since vibration frequencies can be determined significantly more accurately than voltages, this already makes a decisive contribution to the above object. In addition, by applying the voltage to be measured to the trim electrodes, it is achieved that the voltage has a significant influence on the vibration behavior of the sample mass. The voltage applied to the trim electrodes effectively changes the spring constant of the vibration system. An appropriate design of the MEMS, i.e., amongst others, of the mechanical spring constant, allows setting an effective spring constant that is particularly favorable for the detection of frequency changes due to changes in the voltage to be measured. By applying the voltage to be measured to the trim electrodes, it is therefore possible to further increase the measurement accuracy.

Advantageously, the voltage to be measured is a reference voltage, the magnitude of which is the basis for further measurement and/or calculation operations. The method then further includes: correcting the further measurement and/or calculation operations by replacing the anticipated reference voltage with the measured reference voltage. Additional operations, such as analog-to-digital conversions, determination of measured values by means of a scale factor or the like, are therefore not carried out with the reference voltage specified for the production of the reference voltage source, but with the measured voltage value. Similarly, the values of variables derived from the reference voltage (e.g., analog) are updated or corrected based on the measured value of the reference voltage. This improves the result of further measurement and/or calculation operations.

By applying the voltage to be measured to the trim electrodes, between 50% and 90%, preferably between 60% and 80%, more preferably 75% of the mechanical spring force can be compensated for. These compensation values are particularly advantageous for the magnitude of the frequency change following changes in the voltage to be measured. This increases the accuracy of the measurement. The magnitude of the compensation can be achieved by an appropriate design of the MEMS, i.e., particularly the trim electrodes and/or the spring elements and the spring constants specified by them, as soon as the magnitude of the voltage to be measured is known. In this way, particularly sensitive MEMS can be produced that are set to specific voltage values.

The procedure can be carried out in particular when the MEMS is at rest, i.e., when there are no strong vibrations or linear accelerations. This avoids disturbances caused by excessive movement. For example, the procedure can always be carried out whenever the electronic component the reference voltage of which is to be measured is started. In particular, if this is an acceleration sensor, the MEMS can then be expected to be at rest or almost at rest. This allows reliable values to be obtained for the voltage to be measured.

A micro-electro-mechanical system, MEMS, for measuring a voltage includes a sample mass which is mounted above a substrate by means of mechanical spring elements in such a way that it can be moved relative to the substrate along a direction of vibration, trim electrodes which are suitable for generating an electrostatic force on the sample mass when a voltage is applied to them, the electrostatic force counteracting a mechanical spring force generated by the spring elements when the sample mass is deflected along the direction of vibration, drive electrodes which are suitable for setting the sample mass in motion along the direction of vibration, and readout electrodes which are suitable for measuring a vibration frequency of the vibration of the sample mass generated in such a way. The MEMS further includes a control unit which is suitable for controlling the MEMS in such a way that it carries out the procedures described above.

The above-mentioned positive effects can be achieved with such a MEMS.

The MEMS can be designed in such a way that the resonant frequency of the vibration of the sample mass changes by a value from the range of 100 ppm to 1,000 ppm of the resonant frequency when the voltage to be measured is applied to the trim electrodes in case of a change in voltage of 1 mV. The MEMS is therefore designed in such a way that relatively small changes in the voltage applied to the trim electrodes in the millivolt range, i.e., e.g., of approx. 100 ppm at a voltage of 10V, lead to changes in the resonant frequency that are significantly greater than stability fluctuations in the resonant frequency of less than 10 ppm. This then leads to high accuracy when measuring changes in the resonant frequency, which leads to high accuracy when measuring changes in the voltage applied to the trim electrodes.

In this process, the change in resonant frequency with the change in voltage may not depend linearly on the deflection of the sample mass and/or the resonant frequency may change with the ambient temperature. The control unit is then suitable for taking into account these dependencies through calibration when detecting the voltage to be measured. Both the magnitude of the vibration amplitude of the sample mass and changes in the temperature of the components of the MEMS, e.g., due to fluctuations in the ambient temperature, can influence the mechanical spring constant and the electrostatic spring constant produced by the trim electrodes. This results in variously strong changes in the resonant frequency for different deflections of the sample mass and/or temperatures within the MEMS due to a changing voltage at the trim electrodes. This relation is most of the time not linear.

The control unit can therefore be suitable for carrying out calibration of the system, e.g., through known changes in the voltage at the trim electrodes at different vibration amplitudes or temperatures and determining the changes in the resonant frequency resulting therefrom. The relations obtained in this way can be used directly to correct measured values during operation to specific standard values of the vibration amplitude and/or temperature. Conversely, it is also possible to determine the temperature and/or the vibration amplitude by using known changes in voltage from the measured values for the change in the resonant frequency. Calibration is not necessary, for example, when the vibration amplitude is kept constant and/or the measurements are only carried out in a predetermined temperature range.

The MEMS can be designed in such a way that the vibration system generated by the vibrations of the sample mass has a performance of more than 1,000 when the voltage to be measured is applied to the trim electrodes. This makes it particularly easy to measure changes in the resonant frequency.

The sample mass, the spring elements, the trim electrodes, the drive electrodes and the readout electrodes can be evacuated in this process, e.g., by enclosing them in a common, evacuated housing. This leads to an increase in the performance of the system due to the elimination of air resistance, which, in turn, increases the measuring accuracy.

An acceleration sensor for measuring accelerations can include a MEMS as described above. In this process, the MEMS is suitable for measuring an acceleration that acts on the acceleration sensor along the direction of vibration of the sample mass by measuring the vibration frequency of the sample mass. The vibration system of the MEMS is therefore not only used to detect changes in the voltage applied to the trim electrodes, but mainly to measure changes in the vibration due to accelerations applied to the sample mass. In this process, the two signals can be easily distinguished due to the different time constants. Changes in the voltage to be measured have a very long time constant, e.g., months or years, while accelerations naturally have a short-term effect, i.e., in the range of seconds, minutes or hours.

In this process, the voltage to be measured can be equal to a reference voltage for determining an operating voltage applied to the drive electrodes and/or readout electrodes. This means that the voltage to be measured is the voltage that determines the scale factor of the acceleration measurement. This makes it possible to detect and correct changes in the scale factor due to a drift in the reference voltage. In this process, it is particularly advantageous that this can be carried out with the components available for the acceleration measurement, whereby holding stocks of additional components or structures can be prevented. In this way, highly accurate, compact and long-term stable acceleration sensors can be provided.

### BRIEF DESCRIPTION OF THE DRAWINGS

The invention will be further described in the following text, with reference to the figures. This description is to be understood as purely exemplary. The invention is defined solely by the claims.

FIG. 1 shows a schematic representation of a micro-electro-mechanical system, MEMS, for measuring a voltage;

FIG. 2 shows a schematic flow chart of a procedure for measuring a voltage by means of a MEMS;

FIG. 3 shows a schematic representation of a MEMS for measuring a reference voltage;

FIG. 4 shows a schematic representation of another MEMS for measuring a voltage;

FIG. 5 shows a schematic representation of an acceleration sensor comprising a MEMS for measuring a drive and/or readout voltage;

FIG. 6 shows a schematic representation of another MEMS for measuring a voltage; and

FIG. 7 shows a schematic representation of another MEMS for measuring a voltage.

### DETAILED DESCRIPTION

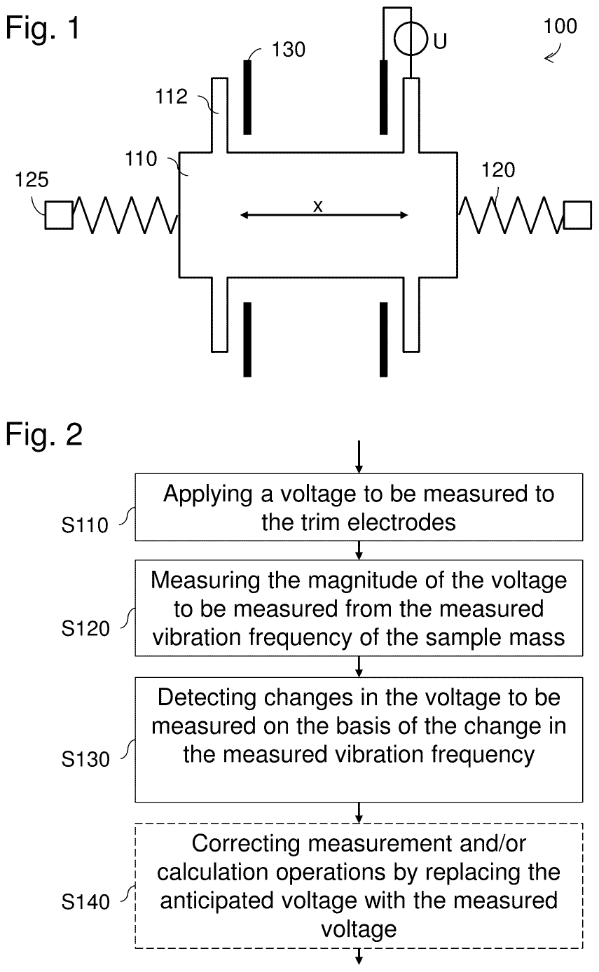

FIG. 1 shows a schematic representation of a micro-electro-mechanical system, MEMS, 100 for measuring a voltage U. The MEMS 100 includes a sample mass 110, mechanical spring elements 120, and trim electrodes 130.

The sample mass 110 is mounted above a substrate by means of the mechanical spring elements 120 in such a way that it can be moved relative to the substrate along a direction of vibration x. In FIG. 1, the substrate lies parallel to the plane of the drawing, e.g., under the sample mass 110 shown. The sample mass 110 can, in principle, assume any shape as long as the effects described in the following text can be achieved with it. Typically, the sample mass 110 will have a planar expansion relative to the substrate, i.e., dimensions parallel to the substrate are far greater than the expansion perpendicular to the substrate.

The spring elements 120 are shown purely symbolically in FIG. 1 and can, in principle, assume any shape that allows guiding the sample mass 110 linearly along a specific direction of vibration x. Vibrations in several different directions of vibration may also be possible. Preferably, however, the spring elements 120 only allow the sample mass 110 to vibrate along the direction of vibration x, i.e., the sample mass 110 is freely movable in the direction of vibration x except for restoring spring forces, while movements perpendicular to the direction of vibration x are strongly suppressed in comparison and are therefore negligibly small. The spring elements 120 are connected to the substrate via anchors 125.

A voltage U can be applied to the trim electrodes 130 relative to the sample mass 110, e.g., by supplying charges to the trim electrodes 130 and/or the sample mass 110. The magnitude of the voltage U can be known in this process.

As shown in FIG. 1, the sample mass 110 can include counter-electrodes 112. The voltage U can then only be applied between a trim electrode 130 and the corresponding counter-electrodes 112. The counter-electrodes 112 can be made of the same material as the rest of the sample mass 110 and be connected to it conductively. However, the counter-electrodes 112 can also be insulated electrically from the rest of the sample mass 110.

The voltage U generates an electrostatic force on the sample mass 110. In this process, the trim electrodes 130 are designed or arranged relative to the sample mass 110 in such a way that the electrostatic force counteracts a mechanical spring force generated by the spring elements 120 when the sample mass 110 is deflected along the direction of vibration x. Therefore, if the spring elements 120 move the sample mass back into its initial position, i.e., to the left, when it is deflected to the right, for example, a force is generated between the trim electrodes 130 and the sample mass 110 in the direction of deflection, i.e., to the right. By changing the voltage U at the trim electrodes 130, the effective spring constant of the entire vibration system can therefore be changed, depending on which part of the mechanical spring force is compensated for by the electrostatic spring force. Similarly, in the event that the voltage U is fixed to a specific range, a specific compensation ratio can be achieved by the configuration of the MEMS 100, i.e., in particular of the sample mass 110, the spring elements 120 and/or the trim electrodes 130. The effective spring constant or difference between the mechanical spring force and the electrostatic force then naturally determines the resonant frequency of the vibration of the sample mass 110 along the direction of vibration x.

The MEMS 100 can have drive electrodes that are suitable for setting the sample mass 110 in motion along the direction of vibration x. The MEMS 100 can also include readout electrodes which are suitable for measuring a vibration frequency of the vibration of the sample mass 110 generated in this way. However, the sample mass 110 can also be set into vibration in other ways, e.g., by movements of the MEMS 100 or by coupling to other vibration systems. Drive electrodes are therefore not absolutely necessary and are therefore not shown in FIG. 1.

Special readout electrodes can also be dispensed with, as the vibration frequency can also be detected via the trim electrodes 130. For example, at a constant voltage U, the change in capacitance of the capacitor formed by the trim electrode 130 and counter-electrode 112 can be established via a charge measurement. This allows the distance to be determined, the time course of which allows the vibration frequency to be determined. However, other readout schemes are conceivable as well. In this case, at least one trim electrode 130 acts as a readout electrode.

The MEMS 100 moreover has a control unit (not shown) which is suitable for controlling the MEMS 100 in such a way that it carries out a procedure for measuring the voltage U applied between the trim electrodes 130 and the sample mass 110. The control unit can be formed on the substrate of the MEMS 100 in this process. However, the control unit can also be arranged externally. The procedure carried out by the MEMS 100 can be summarized schematically with reference to FIG. 2 as follows.

At S110, the voltage U to be measured is applied to the trim electrodes 130, thereby generating the electrostatic force on the sample mass 110, which partially compensates for the mechanical spring force.

At S120, the magnitude of the voltage U to be measured is determined from the measured vibration frequency of the sample mass 110. Since the mechanical properties of the MEMS 100 are, in principle, predetermined by the manufacturing process and are therefore known, the influence of the voltage U on the effective spring constant and thus on the vibration frequency of the sample mass 110 can be determined. Furthermore, it is possible to measure the vibration frequency without and with the voltage U applied to the trim electrodes 130 with otherwise constant operating parameters. The magnitude of the voltage U can also be inferred by comparing the measurement results.

At S130, changes in the voltage U to be measured are determined on the basis of the change in the measured vibration frequency. In particular, small changes in the voltage U in the millivolt range that occur over a long period of time, e.g., over 1 year or 10 years, can be determined with greater accuracy via changes in the vibration frequency than with a direct voltage measurement, as changes in the vibration frequency can be determined with great accuracy.

In this way, small changes in a voltage that is assumed to be constant can be precisely determined over long periods of time. Preferably, by applying the voltage U to the trim electrodes 130, between 50% and 90%, preferably between 60% and 80%, more preferably 75% of the mechanical spring force are compensated for. As will be explained further below, the MEMS 100 is sufficiently sensitive to changes in the voltage U to be measured with such a selection of parameters or such a layout of the MEMS 100.

The procedure is preferably carried out while the MEMS 100 is at rest or when it can be anticipated that a rest position is given, such as during the start of operation of the MEMS 100 or the device in which the voltage U to be measured is used. In principle, the procedure is based on detecting the change in the effective spring constant, which is reflected in a change in the vibration carried out. Since movements and, in particular, accelerations of the MEMS 100 can disturb this vibration, operation at rest is preferable for reliable results. Otherwise, it is necessary to detect and compensate for disturbances.

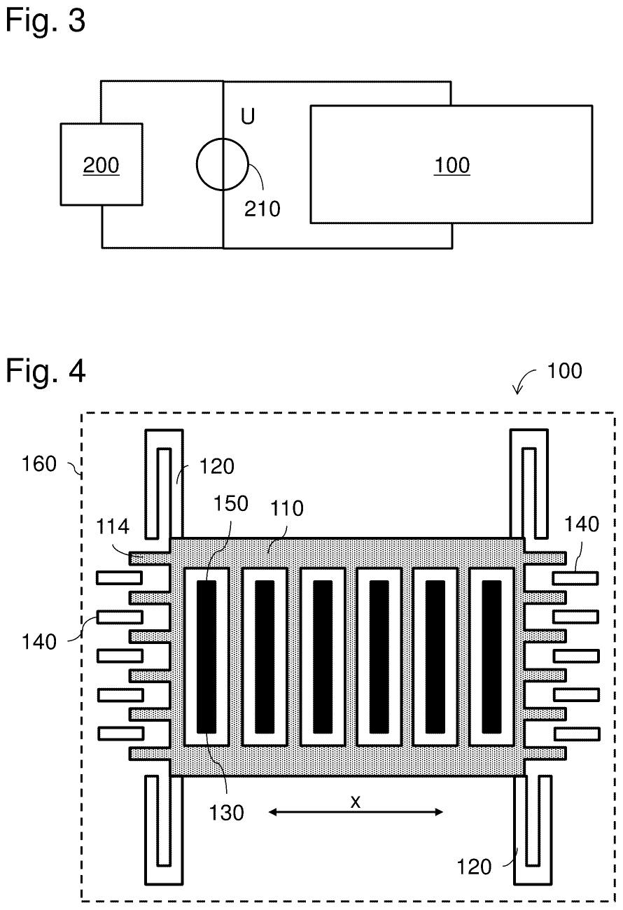

As depicted schematically in FIG. 3, the voltage U to be measured can be a reference voltage, the magnitude of which is the basis for further measurement and/or calculation operations. In this process, the reference voltage U is required for the operation of an electronic component 200, such as a voltage converter, an analog-to-digital converter, a sensor, e.g., an acceleration sensor, and is generated by a reference voltage source 210. The electronic component 200 performs measurement and/or calculation operations based on the reference voltage U. For example, the reference voltage U can serve as a reference or comparison value for various voltage and/or electricity variables used in the electronic component 200. As explained above, measurement results of electronic components 200 configured as sensors can also depend on the magnitude of the reference voltage. The MEMS 100, which is also supplied with the reference voltage U, can, in this process, be part of the electronic component 200 or be available as a separate component.

As symbolized by the dashed line in FIG. 2, the procedure can then optionally further include at S140 that the further measurement and/or calculation operations are corrected by replacing the anticipated reference voltage with the measured reference voltage U. This then allows long-term stable operation of the functions of the electronic component 200 based on the reference voltage.

Particularly preferred are configurations of the MEMS in which the resonant frequency of the vibration of the sample mass 110 changes by a value from the range of 100 ppm to 1,000 ppm of the resonant frequency when the voltage U to be measured is applied to the trim electrodes 130 in case of a change in voltage of 1 mV. This enables a particularly accurate and reliable measurement of the voltage U.

A schematic representation of a design of a MEMS 100 with which the above requirements can be met, for example, is shown in FIG. 4. All components are made of silicon, for example.

As shown in FIG. 4, the sample mass 110 can be designed as a rectangular, perforated pattern in which the trim electrodes 130 are arranged. The trim electrodes 130 thus form plate capacitors with the side faces of the recesses in the sample mass 110 in a space-saving manner.

The sample mass 110 is mounted symmetrically at its four corners above the substrate via spring elements 120 configured as folded bending beam springs. In this process, the bending beam springs extend perpendicular to the direction of vibration x and therefore allow the sample mass 110 to vibrate in this direction, while movements in the other directions are suppressed to a negligible extent.

The vibration of the sample mass 110 is driven by drive electrodes 140 arranged laterally in the direction of vibration x, which engage in counter-electrodes 114 of the sample mass 110. The vibration parameters are read out via the trim electrodes 130, which therefore also serve as readout electrodes 150. However, the drive electrodes 140 can also function as readout electrodes 150, or separate readout electrodes 150 can be provided.

The force acting between the trim electrodes 130 and the sample mass 110 results in an electrostatic spring constant for the vibration of the sample mass, which is defined as follows:

$${k}_{el} ( U ) = - \frac{2 \cdot N \cdot {ε}_{0} \cdot h \cdot L \cdot {U}^{2}}{{d}^{3}} = - g \cdot {U}^{2}$$

wherein N is the number of trim electrodes, h is their height perpendicular to the substrate, L is their length parallel to the substrate and perpendicular to the direction of vibration x, and d is the gap distance between the trim electrodes 130 and the sample mass 110 at rest.

This results in the resonant frequency determined by the effective spring constant k_{eff}:

$$f ( U ) = \frac{1}{2 π} \cdot \sqrt{\frac{{k}_{eff} ( U )}{m}} = \frac{1}{2 π} \cdot \sqrt{\frac{{k}_{m} + {k}_{el} ( U )}{m}} = \frac{1}{2 π} \cdot \sqrt{\frac{{k}_{m} - g \cdot {U}_{in}^{2}}{m}} = \frac{1}{2 π \sqrt{m}} \cdot \sqrt{{k}_{m} - g \cdot {U}_{in}^{2}}$$

wherein m designates the mass of the sample mass 110, and the mechanical spring constant kₘ is given as:

$${k}_{m} = n \cdot {E}_{Si} \cdot \frac{{b}^{3}}{{l}^{3}}$$

wherein n is the number of spring elements, E_{Si} is the modulus of elasticity of silicon, h is the height of the spring elements 120 perpendicular to the substrate, b is their width in the direction of vibration x, and I is their length parallel to the substrate and perpendicular to the direction of vibration x.

The sensitivity of the resonant frequency to changes in the voltage U is then:

$$\frac{df ( U )}{dU} = \frac{- 2 gU}{2 π \sqrt{m} \cdot 2 \cdot \sqrt{{k}_{m} - g \cdot {U}^{2}}} = \frac{- gU}{2 π \sqrt{m} \cdot 2 \cdot \sqrt{{k}_{m} - g \cdot {U}^{2}}} = \frac{- gU}{2 π \sqrt{m \cdot {k}_{m} ( 1 - β )}}$$

if the compensation factor β is introduced, to which the following applies: β·kₘ=g·U².

A high sensitivity can therefore be achieved, for example, by a relatively large voltage U or a large factor g, i.e., the largest possible effective trim electrode area N·L·h with the smallest possible gap distance d. High sensitivity can also be achieved by a small mass m of the sample mass 110 and a small mechanical spring constant kₘ, i.e., by a small width b and a large length l.

If the resolvable change in voltage is quantified as a fraction of the voltage U to be measured with dU=α·U, the resulting relationship between the change in frequency df resulting therefrom and the output frequency f is as follows:

$$df = \frac{- gU}{2 π \sqrt{m \cdot {k}_{m} ( 1 - β )}} dU = \frac{- {gU}^{2}}{2 π \sqrt{m \cdot {k}_{m} ( 1 - β )}} \cdot α == \frac{- β \cdot {k}_{m}}{2 π \sqrt{m \cdot {k}_{m} ( 1 - β )}} \cdot α = - \frac{β}{\sqrt{( 1 - β )}} \cdot α \cdot f$$

The relative frequency stability is approx. 10 ppm, i.e., changes in frequency in the order of magnitude of 10 ppm of the output frequency cannot be quickly identified as a measurement signal. The following is therefore meant to apply:

$$\frac{df}{f} = \frac{β}{\sqrt{( 1 - β )}} \cdot α > 100 ppm$$

If, for example, α=50 ppm is selected, i.e., an already very low value for the drift of reference voltages within a year, then the resulting compensation factor β is:

$$β > 0.828$$

If β is known, the various parameters of the MEMS 100 of FIG. 4 can be adjusted, taking into account the fact that β·kₘ=kₑₗ must apply, resulting in the following specification:

$$\frac{β \cdot {E}_{Si}}{2 \cdot {ε}_{0}} \cdot n \cdot \frac{{b}^{3}}{{l}^{3}} = \frac{N \cdot L \cdot {U}^{2}}{{d}^{3}}$$

Based on these specifications, the MEMS 100 can, in principle, be adapted to any voltages U to be measured, i.e., it is possible to configure the MEMS 100 for the measurement of special reference voltages with a known range of values. In this way, high-precision voltmeters can be achieved for slowly changing voltages.

In addition, it is helpful in this process if the MEMS 100 is configured in such a way that the vibration system generated by the vibrations of the sample mass 110 has a performance of more than 1,000 when the voltage U to be measured is applied to the trim electrodes 130. This makes the resonant frequency of the system particularly easy to measure.

For this purpose, but also to protect the components of the MEMS 100, the MEMS 100 can have a housing 160, which is depicted symbolically in FIG. 4 as a dashed enclosure of the MEMS components. The housing 160 comprises, in particular, the sample mass 110, the spring elements 120, the trim electrodes 130, the drive electrodes 140, and the readout electrodes 150. The housing 160 and thus the MEMS components in the housing 160 can be evacuated. This eliminates the air resistance and the damping resulting therefrom, whereby the performance of the system is (further) improved.

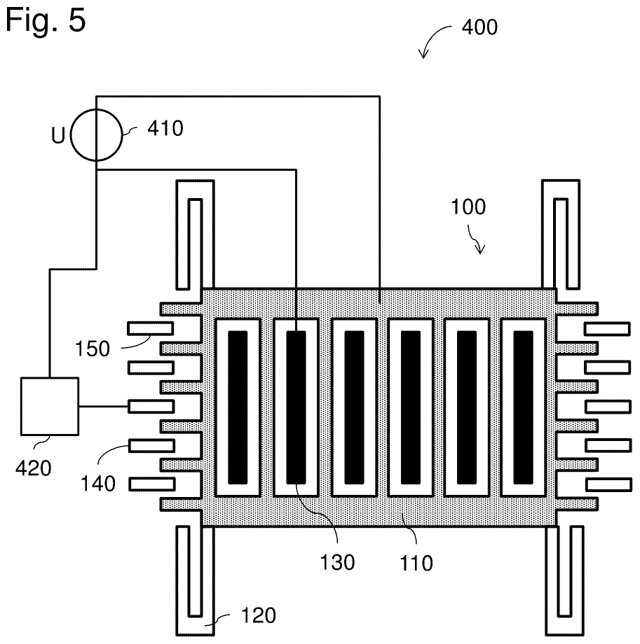

Of particular interest is the use of the technology described above in an acceleration sensor 400. Such an acceleration sensor 400 is shown schematically in FIG. 5.

The acceleration sensor 400 includes the MEMS 100, which is suitable for measuring an acceleration that acts on the acceleration sensor 300 along the direction of vibration x of the sample mass 110 by measuring the vibration frequency of the sample mass 110. For this purpose, the trim electrodes 130 can be used as readout electrodes 150, as shown in FIG. 4. However, it can also be advantageous to detect the vibrations of the sample mass 110 via separate readout electrodes 150. These can be arranged together with the drive electrodes 140 on the sides of the sample mass 110, as shown in FIG. 5. However, the lateral electrodes can be operated both as drive and as readout electrodes by temporal multiplexing.

In this way, any acceleration sensor 400 structured according to the above considerations can also be used as a device for voltage measurement if a separate connection of the trim electrodes 130 to a voltage source is possible. This allows additional functions to be achieved with the acceleration sensor 400 that go beyond mere acceleration measurement.

As also depicted in FIG. 5, the voltage U to be measured is preferably equal to a reference voltage which is used to determine an operating voltage applied to the drive electrodes 140 or the readout electrodes 150. This means that the acceleration sensor 400 comprises a reference voltage source 410. The reference voltage generated by this reference voltage source 410 is applied both to the trim electrodes 130 and to a voltage generator 420. The voltage generator 420 generates the operating voltage for the drive electrodes 140 and/or the readout electrodes 150 from the reference voltage, e.g., by scaling and/or modulating the reference voltage U, for example, in the form of sinusoidal modulation.

As explained above, the scale factor, which converts the measured vibration into an acceleration, is quadratically dependent on the operating voltage and therefore also on the reference voltage U. By applying the reference voltage U to the trim electrodes 130 and monitoring the effects of possible changes in the reference voltage U on the vibration system, a drift in the scale factor can be detected and corrected. In this way, highly accurate and long-term stable acceleration sensors 400 can be provided.

The configuration of the MEMS 100 described above is purely exemplary. A large number of alternative configurations is possible, as long as the objective of bringing about a precisely measurable change in the vibration of the sample mass 110 by changing the voltage at the trim electrodes 130 is achieved. The correct layout for such sensors can be derived by a person skilled in the art analogously to the considerations made above.

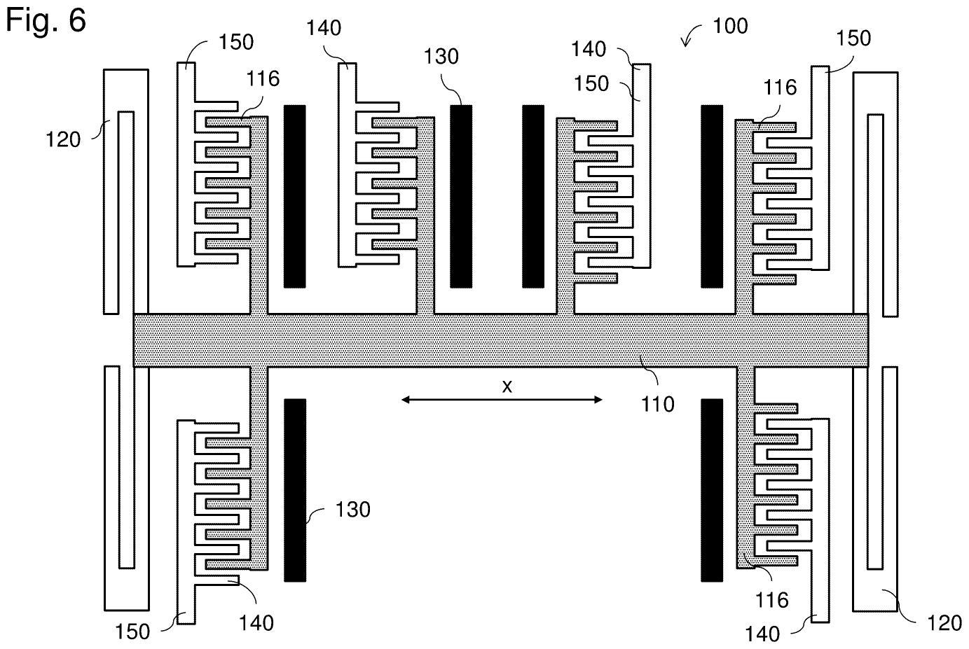

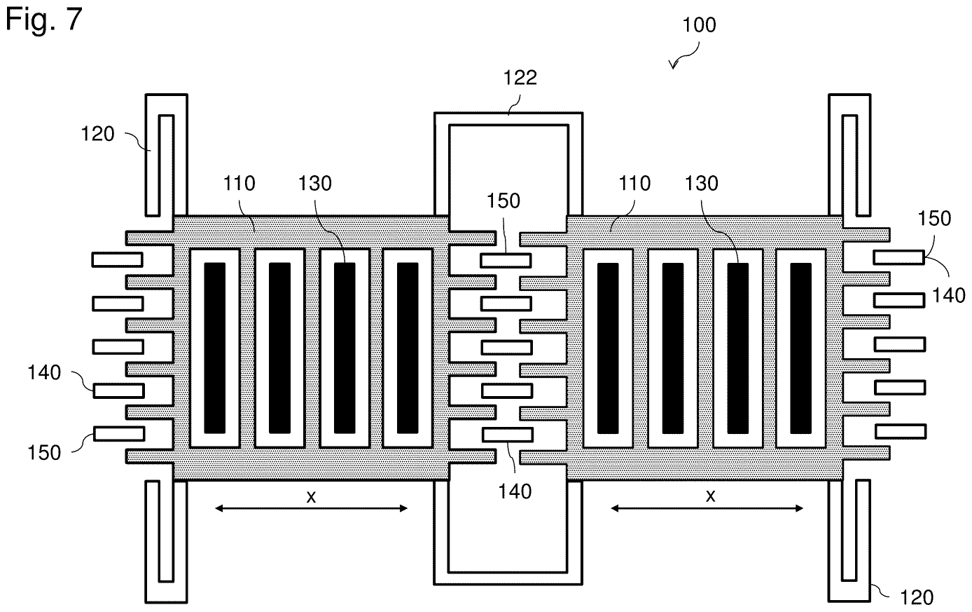

FIGS. 6 and 7 show examples of such alternative configurations. As depicted in FIG. 6, the MEMS 100 can have a sample mass 110, which is configured as a beam extending mainly in the direction of deflection x. On each of its ends, the sample mass 110 is connected to the substrate via two spring elements 120 configured as folded bending beam springs.

Also mounted on the substrate is a row of drive electrodes 140 and readout electrodes 150 configured as comb electrodes, where the same electrode comb can be used both as a drive electrode 140 and as a readout electrode 150. The drive/readout electrodes 140, 150 engage in counter-electrodes 116 arranged on the sample mass 110 in the form of comb electrodes. By applying a voltage between the drive/readout electrodes 140, 150 and the counter-electrodes 116, the sample mass 110 can be set into vibration along the direction of vibration x. The vibration, for example, can be determined by detecting the charge on the electrodes at a constant voltage or by detecting the voltage at a constant charge (i.e., when the current flow to the electrodes is interrupted).

Trim electrodes 130 are mounted on the rear side of the counter-electrodes 116, which counteract the mechanical spring force when a voltage is applied to them. As already described above, the trim electrodes 130 can also function as readout electrodes 130.

FIG. 7 shows a schematic set-up of a MEMS 100, which essentially results from a duplication of the set-up of the MEMS 100 shown in FIG. 4. In this process, two sample masses 110 share a centrally arranged set of drive/readout electrodes 140, 150. In this area, the two sample masses 110 are connected by coupling springs 122, which allow the two sample masses 110 to vibrate (also in opposite directions) along the direction of vibration x. Otherwise, the set-up of each of the halves of the MEMS 100 of FIG. 7 corresponds to that of the MEMS 100 of FIG. 4. A further description is therefore unnecessary.

The two configurations of FIGS. 6 and 7, like many other possible configurations, also make it possible to measure voltages (in particular, reference voltages) by applying the voltages to trim electrodes 130 and monitoring the resulting effects on the vibration behavior. A person skilled in the art therefore has a multitude of possibilities to solve the problem mentioned at the beginning within the scope of the claims.

1-11. (canceled)

12. A method for measuring a voltage by means of a micro-electro-mechanical system (MEMS) comprising a sample mass which is mounted above a substrate by a plurality of mechanical spring elements such that the sample mass can be moved relative to the substrate along a direction of vibration, a plurality of trim electrodes configured to generate an electrostatic force on the sample mass under an applied voltage, the electrostatic force counteracting a mechanical spring force generated by the mechanical spring elements when the sample mass is deflected along the direction of vibration, a plurality of drive electrodes configured to set the sample mass in motion along the direction of vibration, and a plurality of readout electrodes configured to measure a vibration frequency of the vibration of the sample mass, the method comprising:
applying a voltage to be measured to the trim electrodes, wherein the voltage to be measured is a reference voltage having a magnitude which is a basis for further measurement and/or calculation operations;
measuring the reference voltage from a measured vibration frequency of the sample mass;
detecting changes in the reference voltage based on a change in the measured vibration frequency; and
correcting the further measurement and/or calculation operations by replacing the reference voltage with the measured reference voltage.

13. The method of claim 12, wherein by applying the reference voltage to the trim electrodes, between 50% and 90% of the mechanical spring force is compensated for.

14. The method of claim 12, wherein the measuring, the detecting, and the correcting are carried out while the MEMS is at rest.

15. A micro-electro-mechanical system (MEMS) for measuring a voltage, the MEMS comprising:
a sample mass mounted above a substrate by a plurality of mechanical spring elements such that the sample mass can be moved relative to the substrate along a direction of vibration;
a plurality of trim electrodes configured to generate an electrostatic force on the sample mass under an applied voltage, the electrostatic force counteracting a mechanical spring force generated by the mechanical spring elements when the sample mass is deflected along the direction of vibration;
a plurality of drive electrodes configured to set the sample mass in motion along the direction of vibration;
a plurality of readout electrodes configured to measure a vibration frequency of the vibration of the sample mass; and
a control unit configured to control the MEMS such that the MEMS carries out the method of claim 12.

16. The MEMS of claim 15, wherein the MEMS is configured such that a resonant frequency of the vibration of the sample mass changes by a value in a range of 100 ppm to 1,000 ppm of the resonant frequency when the reference voltage is applied to the trim electrodes in case of a change in voltage of 1 mV.

17. The MEMS of claim 16, wherein:
(i) the change in the resonant frequency with the change in voltage does not depend linearly on the deflection of the sample mass; and/or
(ii) the resonant frequency changes with ambient temperature; and
the control unit is configured to account for dependencies (i) and/or (ii) through calibration when detecting changes in the reference voltage.

18. The MEMS of claim 15, wherein the MEMS is configured such that a vibration system generated by the vibrations of the sample mass has a performance of more than 1,000 when the reference voltage is applied to the trim electrodes.

19. The MEMS of claim 15, wherein the sample mass, the spring elements, the trim electrodes, the drive electrodes, and the readout electrodes are evacuated.

20. An acceleration sensor, comprising:
the MEMS of claim 15,
wherein the MEMS is configured to measure an acceleration that acts on the acceleration sensor along the direction of vibration of the sample mass, by measuring the vibration frequency of the sample mass.

21. The acceleration sensor of claim 20, wherein the reference voltage serves to determine an operating voltage applied to the drive electrodes and/or readout electrodes.
